(19) United States
(12) Patent Application Publication
(10) Pub. No.: US 2009/0232984 A1
(43) Pub. Date: Sep. 17, 2009

(54) Apparatus and Method of Film Formation

(76) Inventors: Narishi Gonohe, Shizuoka-ken (JP); Masamichi Harada, Shizuoka-ken (JP); Nobuyuki Kato, Shizuoka-ken (JP)

Correspondence Address: ARENT FOX LLP, 1050 CONNECTICUT AVENUE, N.W., SUITE 400, WASHINGTON, DC, 20036, US

(21) Appl. No.: 11/886,425

(22) PCT Filed: Mar. 13, 2006
(86) PCT No.: PCT/JP2006/304872

§ 371 Date: Nov. 25, 2008

(30) Foreign Application Priority Data
Mar. 17, 2005 (JP) 2005-077764

(51) Int. Cl. C23C 16/44; C23C 16/00

(52) U.S. Cl. 427/255.28; 118/728

(57) ABSTRACT

In a vacuum chamber 42 comprising a film forming chamber 44 and a catalyst chamber 46 including a catalyst source 48 located opposed to a substrate S, the film forming chamber 44 is connected to the catalyst chamber 46 through an opening 47, the catalyst source being displace at a position satisfying ω≧θ, where ω is an angle included between the shortest linear line connecting the periphery of a substrate on the substrate supporting stage with the periphery of the opening and the substrate and where θ is an angle included between the shortest linear line connecting the periphery of the substrate with the edge of the catalyst source and the substrate. By using such a film forming apparatus, a radical produced at the catalyst source can be prevented from being deactivated so that the reaction between a source gas and the radical will be efficiently performed to form the desired film.

### TECHNICAL FIELD

The present invention relates to an apparatus and method of film formation.

### BACKGROUND ART

In recent years, ALD (Atomic Layer Deposition) method has been focused as a technique of film formation in the field of semiconductor device production.

Usually, ALD forms a desired film by causing the surface of a substrate to adsorb the precursor of a source gas at each atomic layer after the source gas has been introduced into a vacuum chamber (absorption step) and then introducing a reactant gas into the vacuum chamber so that the precursor reacts with the reactant gas on the surface of the substrate in such a state as the precursor of a source gas has been adsorbed onto the surface of the substrate (reaction step). The adsorption step onto which the precursor adsorbed onto the substrate and reaction steps which the precursor react with the reactant gas are repeated many times to form a film having the desired thickness.

ALD uses an ordinary raw gas or a radical or ion from plasma decomposition as the aforementioned reactant gas. However, if such reactant gases are used, a reaction between the reactant gas and the precursor on the substrate cannot produce sufficiently to form a film having the desired properties. Therefore, this may form a film containing impurities more or a film having its increased resistivity and also raise another problem in that the adhesion between the formed film and the underlying layer is inferior.

There is also known catalysis CVD which forms a film by using a chemical reaction between a source gas and a reactant gas as in the aforementioned ALD. This CVD is a method which produces a radical by bringing the reactant gas into contact with a catalyst and causes the radical to react with the source gas on a substrate (e.g., see Patent Document 1). According to this method, a large amount of radical can be produced sufficiently to create a reaction between the radical and a source gas. As a result, a film less containing impurities and having the desired properties can be formed. Additionally, there is no risk of the film being damaged on a substrate unlike case where the radical is generated by plasma.

Thus, it has been proposed to use a radical generated by a catalytic action as reactant gas even in the ALD.

However, the source gas will deposit on a catalyst source used for producing the radical because the ALD usually makes the production of radical and the introduction of source gas in the same vacuum chamber. As a result, there is a risk in that the catalyst source reacts with the source gas to form a film of a metal contained in the source gas on the catalyst source. In this case, it may be considered that the catalyst source is located apart from the inlet port for the source gas so that the source gas will not deposit on the catalyst source. However, this reduces the efficiency of transportation for the radical. In other words, the radical deactivates during transportation so that a film having the desired properties cannot be formed.

There is known such film forming apparatuses as shown in FIGS. 1 and 2, which are so constituted that a source gas will not deposit on a catalyst source. Each of these film forming apparatuses comprises a catalyst chamber 3 connecting to a reactant gas supply means 1 and including a catalyst source 2 located therein, and a film forming chamber 5 including a substrate supporting stage 4 located therein. Since the catalyst chamber 3 is connected to the film forming chamber 5 through a radical transportation passage, the catalyst source 2 will be far separated from the film forming chamber 5. As a result, the source gas is hard to deposit on the catalyst source. The film forming apparatus of FIG. 1 has an L-shaped radical transportation passage 6 while the film forming apparatus of FIG. 2 comprises an I-shaped radical transportation passage 7.

The transportation efficiency of radical was checked using the apparatuses of FIGS. 1 and 2 as follows.

In each apparatus, a substrate S was placed on the substrate supporting stage 4 within the film forming chamber 5 and the catalyst source 2 was heated to a temperature of 1,750 degrees Celsius. Here, each of the substrates S was an 8-inch wafer which includes a thermal oxide film formed thereon and a copper oxide film further formed on the thermal oxide film.

Thereafter, H₂ gas as reactant gas was introduced from the reactant gas supply means 1 into the catalyst chamber 3 at a rate of 100 sccm for one minute. The transportation efficiency of radical was checked by evaluating whether or not the copper oxide film was deoxidized by the H radical produced from contact of the H₂ gas with the catalyst source 2.

This evaluation was performed by measuring the absolute reflectivity in the formed film before and after the radical irradiation. According to the fact that the copper oxide film is deoxidized to transform into a film of copper when the copper oxide film is irradiated by the radical, the absolute reflectivity in the film is measured before and after the radical irradiation to check the deoxidization efficiency or the transportation efficiency of how much radical is transported to the substrate S. The results are shown in FIG. 3. It is noted that the absolute reflectivity of the copper oxide film is 9% and the absolute reflectivity of the copper film is 54%.

In the film forming apparatus of FIG. 1, the absolute reflectivity of the film after the radical irradiation was 10% (see Point A in FIG. 3). This shows that the absolute reflectivity of the film after the radical irradiation is substantially equal to the reflectivity of the copper oxide film of 9% and that the produced radical did not reach the copper oxide film on the substrate S. It seems that substantially all the radical produced in the catalyst chamber 3 is deactivated by colliding against the wall in the L-shaped transport passage 6 and others when it is transported to the substrate S.

In the film forming apparatus of FIG. 2, the absolute reflectivity after the radical irradiation was 38% (see Point B in FIG. 3). Only the central portion of substrate S was deoxidized. This shows that the produced radical reached the central portion of the oxide film on the substrate S, but did not reach the other parts of the substrate. It seems that this is because substantially all the radical produced in the catalyst chamber 3 was deactivated by colliding against the walls in the I-shaped transport passage 7, catalyst chamber and others.

In such a manner, the prior art could not form the desired film since the radical was deactivated during the transportation so that the amount of radial sufficient to react with the source gas did not reach the substrate.

### [Patent Document 1]

Japanese Laid-Open Patent Publication No. 2000-243712 (in particular, see claims).

### SUMMARY OF THE INVENTION

### Subject to be Attained by the Invention

The subject of the present invention is to solve the aforementioned problems in the prior art. Thus, the present invention provides an apparatus and method of film formation which can prevent a radical produced at a catalyst source from being deactivated during transportation and which can effectively perform the reaction of the radical with the precursor of a source gas to form a film having the desired properties.

### Means to Attain the Subject

A film forming apparatus of the present invention comprises a vacuum chamber including a film forming chamber provided with a source gas supply means and a substrate supporting stage, and a catalyst chamber including a reactant gas supply means and a catalyst source located opposed to the substrate, the film forming chamber being connected to the catalyst chamber through an opening, said apparatus being characterized by that the catalyst source is placed at a position satisfying ω≧δ, where ω is an angle included between the shortest linear line connecting the periphery of a substrate on the substrate supporting stage with the periphery of the opening and the substrate and where δ is an angle included between the shortest linear line connecting the periphery of the substrate with a point spaced apart from the periphery of the catalyst source toward the center thereof by a predetermined distance and the substrate.

The predetermined distance is defined by 0-35% of the length of the catalyst source. The main transport passage of the radical produced at the catalyst source will be inside of the shortest linear line connecting between the periphery of the substrate and the periphery of the catalyst source. Therefore, the most of the main radical transport passage will not be interrupted by the inner wall of the vacuum chamber if the above condition of angle, ω≧δ, is satisfied. As a result, the minimum amount of radical for reaction can reach the substrate.

In a preferred aspect of the film forming apparatus according to the present invention, the predetermined distance from the edge of the aforementioned catalyst source is equal to zero. In other words, the film forming apparatus comprise a vacuum chamber including a film forming chamber provided with a source gas supply means and a substrate supporting stage, and a reactant gas supply means and a catalyst chamber including a catalyst source located opposed to the substrate, the film forming chamber being connected to the catalyst chamber through an opening, said film forming apparatus being characterized by that the catalyst source is disposed at a position satisfying ω≧θ and preferably ω>θ, where ω is an angle included between the shortest linear line connecting the periphery of a substrate on the substrate supporting stage with the periphery of the opening and the substrate, and where θ is an angle included between the shortest linear line connecting the periphery of the substrate with the edge of the catalyst source and the substrate.

If the catalyst source is disposed at the position satisfying ω≧θ, the radical produced at the catalyst source can be transported to the substrate without being deactivated by the inner walls of the vacuum chamber, and react with all the precursors adsorbed by the substrate to form a film having the desired properties.

In such a manner, if the condition of angle, ω≧δ or ω≧θ, is satisfied, the amount of radical required for reaction can reach the substrate without being deactivated, so that a film having the desired properties can be formed. Thus, the catalyst source is not necessarily larger in size than the substrate as in the prior art.

Preferably, the film forming apparatus further comprises a shower nozzle located within the film forming chamber for supplying the source gas and including a central opening formed therethrough, wherein the shower nozzle is disposed at a position satisfying φ≧θ, where φ is an angle included between the shortest linear line connecting the periphery of the substrate with the edge of opening of the shower nozzle and the substrate and where θ is an angle included between the shortest linear line connecting the periphery of the substrate with the edge of the catalyst source and the substrate. If such an angular relationship is satisfied, the produced radical can be transported to the substrate without being deactivated by collision with the shower nozzle.

It is preferred that the distance between the catalyst source and the substrate is in the extent of 0.5-1.5 times of the substrate's diameter. If such a distance is less than 0.5 times, the source gas will undesirably react with the catalyst source. If the distance exceeds 1.5 times, the effect of the radical will be lowered not to form the desired film.

It is preferred that the catalyst source is made of a spiral wire of high-melting-point metal. If such a spiral wire is used, the area in contact with the reactant gas is increased unlike the case when a linear wire is used. Thus, more radical can be effectively produced to form a film having the desired properties. It is further preferred that the high-melting-point metal wire is not bent due to heat. When the wire is bent, it raises a problem in that the high-melting-point metal wire is brought into contact with another high-melting-point metal wire or other part of this device to cause an electrical short-circuit. In order to prevent such a bending, the high-melting-point metal wire may be disposed and held under an appropriate tension to form a catalyst source. If the high-melting-point metal wire is disposed as it is in its bent state, it tends to be bent by heat easily.

Said opening may be provided with a perforated partition. In this case, the total area of perforation in said partition is preferably equal to 50% or more of the surface area of the partition to prevent the radical from being deactivated. It is also preferred that the opening is provided with an isolation valve or shutter to prevent the source gas from depositing on the catalyst source.

The bottom of the film forming chamber may be provided with an evacuation means. When the evacuation means is located at the bottom of the film forming chamber, the produced radical can be more easily guided toward the substrate. This enables the radical to be transported to the substrate more efficiently.

Preferably, the film forming apparatus of the present invention comprises a cooling means inside or outside of the catalyst chamber to keep a fixed temperature in the catalyst chamber.

The film forming method of the present invention is characterized by forming a film using the aforementioned film forming apparatus.

### ADVANTAGES OF THE INVENTION

The film forming apparatus of the present invention has an advantage that the radical produced at the catalyst source can be prevented from being deactivated during the transportation so that the reaction of the radical with the source gas can be more efficiently performed to form a film having the desired properties.

### BEST MODE FOR CARRYING OUT THE INVENTION

The outline of a film forming apparatus according to the present invention is schematically shown in FIG. 4.

The film forming apparatus of the present invention comprises a vacuum chamber 42 having an evacuation means 41.

The vacuum chamber 42 includes a film forming chamber 44 having a source gas supply means 43 and a catalyst chamber 46 having a reactant gas supply means 45.

The film forming chamber 44 includes a substrate supporting stage 441 for receiving a substrate S, which is located within the film forming chamber 44 at its bottom.

The film forming chamber 44 also includes a source gas inlet port 442 formed in the side wall thereof. A source gas is introduced from the source gas supply means 43 through the source gas inlet port 442 into the film forming chamber 44 via a piping 431.

This introduction of the source gas may be attained by using a single tube-shaped nozzle. Preferably, however, such a shower nozzle 443 as shown in the FIG. 4 may be provided immediately below an opening 47 between the catalyst chamber 46 and the film forming chamber 44 so that the precursor of the source gas can be uniformly adsorbed by the substrate S. The shower nozzle 443 is provided with a central opening 444 so that the radical transport passage within the vacuum chamber 42 will not be interrupted.

The film forming chamber 44 is connected to the catalyst chamber 46 through the opening 47. In FIG. 4, the internal diameter of the catalyst chamber 46 is shown to be equal to the diameter of the opening 47. The diameter of the opening 47 may be smaller than the internal diameter of the catalyst chamber 46. For example, as shown in FIG. 6, a partition member 51 may be located between the film forming chamber 44 and the catalyst chamber 46 at the periphery of the opening 47 so that the diameter of the opening 47 can be adjusted. This partition member may be integrated with the vacuum chamber.

The catalyst chamber 46 preferably includes its inner wall coated with quartz or alumina to prevent the deactivation of the produced radical. The top wall of the catalyst chamber 46 is provided with a reactant gas inlet port 461. The reactant gas inlet port 461 is connected to the reactant gas supply means 45 through a piping 451. A reactant gas supplied from the reactant gas supply means 45 is introduced into the catalyst chamber 46 through a piping 451.

The catalyst chamber 46 further comprises a catalyst source 48 which is located at a position opposed to the substrate S placed within the film forming chamber 44. This catalyst source 48 is preferably positioned vertically relative to the passage for introduction of the reactant gas so that the reactant gas can be brought into contact with the catalyst source in the vertical direction.

The catalyst source 48 will be described with reference to FIG. 5 wherein parts similar to those of FIG. 4 have similar reference numerals.

The catalyst source is disposed at a position satisfying ω≧δ, where ω is an angle included between the shortest linear line connecting the periphery of a substrate S on the substrate supporting stage 441 with the periphery of the opening 47 and the substrate and where δ is an angle included between the shortest linear line connecting the periphery of the substrate with a point spaced apart from the periphery of the catalyst source 48 toward the center thereof by a predetermined distance x and the substrate. In this case, ω and δ are angles included between the respective shortest linear lines and the radius of the substrate.

A preferred position at which the catalyst source 48 is located will be described with reference to FIG. 6 wherein similar parts to those of FIG. 4 have similar reference numerals. Such a position as shown in FIG. 6 is taken when the predetermined distance x in FIG. 5 is equal to zero. Namely, the catalyst source is disposed at a position satisfying ω≧θ and preferably ω>θ, where ω is an angle included between the shortest linear line connecting the periphery of the substrate S with the periphery of the opening 47 and the substrate S and where θ is an angle included between the shortest linear line connecting the periphery of the substrate with the edge of the catalyst source 48 and the substrate. The reason why the catalyst source is preferably located at the position satisfying ω>θ is that if ω=θ, the radical may be deactivated as by colliding against the inner wall A of the catalyst chamber 46. In this case, the angle θ is included between the shortest linear line and the radius of the substrate.

It is preferred that this angular relationship of ω≧θ is established at all the points on the periphery of the substrate so that the catalyst source can be seen from all the points on the substrate S. For example, when the diameter of the opening 47 is equal to the internal diameter of the catalyst chamber 46, an angle included between the shortest linear line L1 connecting the periphery a of the inner wall A of the catalyst chamber 46 (i.e., the periphery of the opening 47) with the periphery of the substrate S and the substrate will be set to be ω. Furthermore, if the diameter of the opening 47 is smaller than the internal diameter of the catalyst chamber 46, or if the film forming chamber 44 is separated from the catalyst chamber by the partition member 51 located along the periphery of the opening, an angle ω′ included between the shortest linear line L2 connecting the periphery a′ of the partition member (i.e., the periphery of the opening) with the periphery of the substrate S and the substrate S will be set to be ω.

In any case, the aforementioned angular relationship of ω≧δ or ω≧θ must be established. Whatever shape the vacuum chamber 42 has and also whatever shape the opening 47 has, the produced radical will be deactivated as by the inner wall of the vacuum chamber if the aforementioned angular relationship is not satisfied.

The shower nozzle 443 located within the film forming chamber 44 will be described with reference to FIG. 7 wherein similar parts to those of FIG. 4 have similar reference numerals. The shower nozzle must be disposed at a position satisfying φ≧θ, where φ is an angle included between the shortest linear line connecting the periphery of the substrate S with the periphery b of the central opening 444 in the shower nozzle 443 and the substrate and where θ is an angle included between the shortest linear line connecting the periphery of the substrate with the edge of the catalyst source 48 and the substrate. If such an angular relationship is not satisfied, the radical produced at the catalyst source will be deactivated by colliding against the shower nozzle 443. The aforementioned angular relationship is preferably φ>θ. If φ=θ, the radical may be deactivated by colliding against the side wall B of the opening 443.

The catalyst source 48 is formed from one or more wires of metal having a high melting point. The high-melting-point metals include tungsten, molybdenum, zirconium, tantalum, rhenium, osmium and iridium. This high-melting-point metal wire may be in the form of a linear wire, but preferably in the form of a spirally wound wire as shown in FIG. 8.

In particular, the shape of the catalyst source is not limited in the present invention. For example, the catalyst source may be formed into a polygonal configuration consisting of a plurality of high-melting-point metal wires 81. Further, the surface area of the catalyst source 48 may be increased by suitably assembling a plurality of high-melting-point metal wires into the above polygon. Additionally, the melting point metal wires 81 may be formed into meshes. FIG. 8 exemplifies a catalyst source in which eight high-melting-point metal wires 81 are formed into an octagonal configuration and in which four high-melting-point metal wires are arranged into a square with four high-melting-point metal wires being further arranged into another square within the first-mentioned square. It is preferred that these high-melting-point wires 81 are located so that they will not be thermally bent.

The catalyst source 48 is connected to a power supply (not shown). When the power supply is switched on to flow direct or alternating current through the catalyst source, the catalyst source can be heated to a raised temperature. A control mechanism (not shown) for monitoring and feeding back the current and voltage in the catalyst source is located in the catalyst source to keep the temperature of the catalyst source 48 constant. The temperature of the catalyst chamber 46 will be increased by heat from the catalyst source 48. It is thus preferred that a cooling means (not shown) is located outside or inside of the catalyst chamber to keep the temperature of the catalyst chamber constant.

The distance between the catalyst source 48 and the substrate S is preferably 0.5-1.5 times larger than the diameter of the substrate. Such a distance is set based on the diameter of the substrate rather than the absolute distance for such a purpose that the flow of the radical will be always maintained constant relative to the diameter of the substrate.

If the catalyst source 48 is placed under the aforementioned condition, the amount of radical sufficient to react with the precursor of the source gas adsorbed onto the substrate can be transported to the substrate S without deactivation to form a film having the desired properties.

It is further preferred that the catalyst chamber 46 includes a purge gas supply means (not shown) for preventing the source gas from diffusing in the catalyst chamber and depositing on the catalyst source 48.

Any perforated partition similar to the shower nozzle may be provided in the opening 47 between the catalyst chamber 46 and the film forming chamber 44. Such a partition must be coated with quartz or alumina for effectively preventing the deactivation of the radical. The total area of perforation in the partition should be equal to or larger than half of the surface area in the partition. If the total area of perforation in the partition is less than half of the surface area in the partition, the most of the radical will be deactivated by colliding against the partition. Thus, the amount of radical required to react with the precursor of the source gas adsorbed on the substrate will not reach the substrate to form a film having the desired properties.

The opening 47 may further include a shutter or isolation valve for preventing the source gas from diffusing in the catalyst chamber 46. Preferably, the isolation valve is a gate valve.

The evacuation means 41 may be located in the bottom of the film forming chamber 44 rather than on the sidewall of the film forming chamber 44 as shown in FIG. 4.

A method of forming a film by using the film forming apparatus of the present invention will be described with reference to FIG. 4.

The film forming apparatus of the present invention may be used to perform a pre-treatment before a film is formed as follows.

Firstly the substrate S is placed on the substrate supporting stage 441 and the catalyst source 48 is then energized and heated. The power to the catalyst source 48 has been previously set to be a direct current of 13.0V and 14.0 A, for example. This raises the temperature of the catalyst source to about 1,700 degrees Celsius. The reactant gas is supplied from the reactant gas supply means 45 into the catalyst chamber 48 in the rate of 200 sccm for one minute while the temperature of the catalyst source is maintained at the above level. At the same time, the vacuum chamber 42 is evacuated by the evacuation means 41 in the film forming chamber 44 so that the internal pressure in the vacuum chamber 42 is in the range of 1-60 Pa.

The reactant gas may be any gas containing hydrogen atoms, such as H₂ gas, SiH₄ gas, NH₂NH₂ gas, NH₃ gas or H₂O gas. These gases may be used solely or in any combination.

The reactant gas is brought into contact with the catalyst source 48 to produce a radical which in turn deoxidizes any metal oxide remaining on the surface of the substrate S to expose the clean metal surface of the substrate S. For example, H radical will be produced if the reactant gas is H₂ gas. If the reactive gas is NH₃ gas, the other radical such as NH or NH₂ will be produced.

The radical thus produced has a extremely high reactivity to provide a property of high deoxidization. It can easily deoxidize the metal oxide, fluoride or carbide on the surface of the substrate to expose the clean surface even at a temperature equal to or lower than 200 degrees Celsius. This can improve the nucleation frequency in the precursor of the source gas and the adhesion between the resulting film and the underlying layer.

The aforementioned pre-treatment can be used to clean not only the substrate S, but also the inside of the vacuum chamber 42.

Subsequently, a film forming method which is to be preformed for the thus pre-treated substrate S using the film forming apparatus of the present invention will be described.

After the supply of the reactant gas used in the pre-treatment has been stopped, the temperature of the substrate supporting stage 441 is raised to increase the temperature of the substrate to a range of 200-300 degrees Celsius. After the temperature of the substrate has stabilized, a purge gas is then introduced into the catalyst chamber 46. The purge gas may be any noble gas such as Ar or Xe or any inert gas such as N₂.

Thereafter, the source gas is introduced into the film forming chamber 44 in the rate of 0.5 g/min while introducing the purge gas thereinto. Thus, the precursor of the source gas is adsorbed onto the substrate S. Here, the material of the source gas is particularly not limited if it is an organic metal compound and can be freely selected depending on the type and property of the desired film. For example, the source gas may be selected from a group consisting of Ta [NC (CH₃)₂C₂H₅] [N (CH₂)₂]₃ (TIMATA), penta dimethylamino tantalum (PDMAT), tert-amyl imide tris (dimethylamide) tantalum (TAIMATA), penta-diethylamino tantalum (PEMAT), tert-butyl imide tris (dimethylamide) tantalum (TBTDET), tert-butyl imide tris (ethylmethyl amide) tantalum (TBTEMT) and TaX₅ (wherein X indicates halogen atom selected from fluorine, chlorine, bromine or iodine).

When the source gas has been introduced for 10 seconds, the introduction of the source gas is stopped. On the other hand, the purge gas continues to be introduced to exhaust any remaining source gas. After the source gas has been completely exhausted, the introduction of the purge gas is stopped.

Subsequently, the reactant gas is introduced through the reactant gas inlet port 461 in the rate of 200 sccm for 10 seconds. The reactant gas may be such a gas containing hydrogen atoms as described above, but may be used solely or in a combination of two or more gases.

The introduced reactant gas contacts with the catalyst source 48 to produce a radical. The produced radical reacts with the precursor adsorbed onto the surface of the substrate to form a film. For example, if the material used is TIMATA, a film of TaNₓ will be formed.

The aforementioned steps are repeated many times to obtain a film having the desired thickness.

Several examples of the present invention will be described in detail, but it is to be understood that the present invention is not limited to these examples at all.

### Example 1

The transportation efficiency of radical was checked when the size of opening 47 was changed using the film forming apparatus shown in FIG. 9. The film forming apparatus was provided with the partition member 51 located at the opening 47. By changing the size of this partition member 51 to change the size of the opening 47, the distance y between a point at which the shortest linear line connecting the periphery of the substrate S with the periphery of the opening 47 intersects the catalyst source 48 and the edge of the catalyst source can be changed. The high-melting-point metal wire 81 forming the catalyst source 48 was made of tungsten and had its length z of 100 mm. It is noted that similar parts to those of FIG. 4 have similar reference numerals in FIG. 9.

When the distance y from the catalyst was changed to 0 mm, 35 mm, 40 mm and 45 mm respectively by changing the size of the partition member 51 in the aforementioned arrangement, the radicals produced for the respective distances were deoxidized.

First of all, each of 8-inch wafers provided by forming a thermal oxide film and then a copper oxide film thereover was used as a substrate S, and placed on the substrate supporting stage 441. The catalyst source 48 was then energized and heated. The power to the catalyst source 48 was set to be a direct current of 13.0V and 14.0 A so that the temperature of the catalyst source 48 would be raised to 1700-1800 degrees Celsius. The reactant gas, H₂ gas, was supplied from the reactant gas supply means into the catalyst chamber 46 in the rate of 200 sccm for one minute while the temperature of the catalyst source was maintained at the above level. At the same time, the film forming chamber 44 was evacuated by the evacuation means so that the internal pressure of the vacuum chamber 42 was equal to 10 Pa. The supplied H₂ gas contacted the catalyst source 48 and produced H radical. Whether or not the copper oxide film on each substrate S was deoxidized by such a radical was evaluated by measuring the relative reflectance on the substrate S at each of various points. The results are shown in FIG. 10.

In FIG. 10, the axis of abscissas shows a distance between any point of measurement in a film on the substrate S after it has been irradiated by the radical and the center of the substrate S while the axis of ordinate shows the relative reflectance on the film after the film has been irradiated by the radical, assuming that the reflectivity of the copper film is 100%.

It can be understood from FIG. 10 that, if the distance y is 0 mm, the relative reflectance in the deoxidized copper oxide film is 100% at all points on the substrate. This is equal to the reflectivity in the copper film. When the distance y is 35 mm, that is, when the distance y from the end of the catalyst source is 35% of the length of the catalyst source and if the measurement is made at a position spaced apart from the central portion of the substrate by 45 mm or less, the relative reflectance is 100% similar to that of the copper film. However, the relative reflectance is less than 100% at any position spaced apart from the central portion of the substrate by a distance exceeding 45 mm. When the distance y is 40 mm and 45 mm, the relative reflectance is less than 100% at all points on the substrate. This indicates that the relative reflectance drastically decreases as the distance from the center of the substrate increases.

It can be understood from the above matters that, if the distance y from the end of the catalyst source is equal to or smaller than 35% of the length of the catalyst source, the amount of radical required to form the film can reach the substrate without deactivating.

### Example 2

The transportation efficiency of radical was checked using the film forming apparatus of FIG. 4 having no shower nozzle 443. In this film forming apparatus, the diameter of the opening 47 was equal to the internal diameter of the catalyst chamber 46. Each of 8-inch wafers provided by forming a thermal oxide film and then a copper oxide film thereover was used as a substrate S. The substrate S was placed on the substrate supporting stage 441. The angle ω included between the shortest linear line connecting the periphery of substrate S with the periphery of the opening 47 and the substrate was about 80 degrees.

The catalyst source 48 was formed by arranging eight high-melting-point metal wires 81 made of tungsten and each having its length of 350 mm and its diameter of 0.5 mm into such an octagonal configuration as shown in FIG. 8, by arranging four high-melting-point metal wires 81 each having its diameter of 0.5 mm and its length of 300 mm into a regular square configuration within the octagonal configuration and further by arranging four high-melting-point metal wires 81 each having its a diameter of 0.5 mm and its length of 300 mm into a smaller regular square configuration within the first-mentioned regular square configuration. Such a catalyst source 48 was positioned opposed to the substrate S and spaced apart from the substrate by a distance of 400 mm. The angle θ included between the shortest linear line connecting the periphery of the substrate S with the edge of the catalyst source 48 and the substrate was about 80 degrees. Therefore, this apparatus satisfied the angular relationship of ω≧θ.

In such an arrangement, the catalyst source 48 was energized and heated. The power to the catalyst source 48 was set to be a direct current of 13.0V and 14.0 A so that the temperature of the catalyst source 48 would be raised to 1700-1800 degrees Celsius. The reactant gas, H₂ gas, was supplied from the reactant gas supply means 45 into the catalyst chamber 46 in the rate of 200 sccm for one minute while the temperature of the catalyst source was maintained at the above level. At the same time, the film forming chamber 44 was evacuated by the evacuation means 41 so that the internal pressure of the vacuum chamber 42 was equal to 10 Pa.

H₂ gas contacted the catalyst source 48 and produced H radical. This radical reached to the surface of the substrate S through the radical transportation passage and deoxidized the copper oxide film thereon. The results are recorded in FIG. 3.

It can be understood from FIG. 3 that the absolute reflectivity of the film after it has been treated by the radical is equal to 54% which is the absolute reflectivity of the copper film formed on the substrate S having the thermal oxide film (see Point C in FIG. 3). This means that all the copper oxide film on the substrate have been deoxidized to form a copper film by the produced radical. It is found from this that, if the film forming apparatus of the present invention is used, the substrate S can be efficiently irradiated by the radical without deactivation during transportation.

### Example 3

By using the film forming apparatus shown in FIG. 4, the properties of the formed films of TaNₓ were evaluated. Substrates S used were 8-inch wafers identical to those of the example 1.

First, each of the substrates S was placed on the substrate supporting stage 441 in the film forming chamber 44. The temperature of substrate supporting stage 441 was set at 250 degrees Celsius. After the temperature of the substrate had stabilized, N₂ gas as purge gas was introduced into the catalyst chamber 46 in the rate of 200 sccm.

After five seconds from the introduction of purge gas, TIMATA as source gas was introduced through the shower nozzle 443 in the rate of 0.5 g/min.

After the precursor of the source gas had been adsorbed by the substrate S, the introduction of source gas was stopped.

The introduction of purge gas to the catalyst chamber 46 was stopped after few seconds from the stoppage of introduction of the source gas.

Then, H₂ gas, as reactant gas, was introduced into the catalyst chamber 46 in the rate of 200 sccm and brought into contact with the catalyst source 48 to produce H radical which in turn reacted with the precursor absorbed by the substrate S to form a film. After 10 seconds from the introduction of the reaction gas, the introduction of H₂ gas was stopped.

After the aforementioned procedures had been repeated 200 times, the specific resistance of each of the resulting films of TaNₓ each having its thickness of 18 nm was measured. The results are shown in FIG. 11. As comparative examples, the specific resistance of each of films of TaNₓ formed under the same condition was measured except use of the film forming apparatuses each having no structure satisfying the condition of ω≧θ as in FIGS. 1 and 2. The results are shown in FIG. 11.

The specific resistance of each of the films of TaNₓ produced by the film forming apparatuses having such structures shown in FIGS. 1 and 2 was about 106 (μΩ·cm) (see Points A and B in FIG. 11), namely, the films were substantially insulating films. This is considered because the radical produced at the catalyst source 48 could not reach the substrate due to deactivation in the transportation passage.

On the other hand, the specific resistance of a film of TaNₓ formed using the film forming apparatus of the present invention was of about 800 (μΩ·cm) (see Point C in FIG. 11). This indicates that the film formed by using the film-forming apparatus of the present invention is extremely low in specific resistance in comparison with the films formed by using the apparatuses of FIGS. 1 and 2. This is considered because in the apparatus of the present invention, the film having its extremely low specific resistance was formed by efficiently transporting the produced radical to the substrate so that the sufficient amount of radical reacts with the precursor adsorbed onto the substrate.

### INDUSTRIAL APPLICABILITY

The film forming apparatus and method according to the present invention can form the desired film since the radical produced by the catalytic action can be effectively transported to the substrate without deactivation. Therefore, the present invention can be applied to the film formation process in the field of semiconductor device.

### BRIEF DESCRIPTION OF THE DRAWINGS

FIG. 1 is a schematic view of a film forming apparatus having an L-shaped radical transportation passage.

FIG. 2 is a schematic view of a film forming apparatus having an I-shaped radical transportation passage.

FIG. 3 is a graph illustrating the absolute reflectivities of films after irradiated by radical.

FIG. 4 is a schematic view showing one embodiment of a film forming apparatus according to the present invention.

FIG. 5 is a schematic view illustrating the position of a catalyst source in a film forming apparatus of the present invention.

FIG. 6 is a schematic view illustrating the position of a catalyst source in another film forming apparatus of the present invention.

FIG. 7 is a schematic view illustrating the position of a shower nozzle in a film forming apparatus of the present invention.

FIG. 8 is a schematic view illustrating the shape of a catalyst source in a film forming apparatus of the present invention.

FIG. 9 is a schematic view illustrating another embodiment of a film forming apparatus according to the present invention.

FIG. 10 is a graph illustrating the relative reflectances of films after irradiated by radical produced by the film forming apparatus of FIG. 9.

FIG. 11 is a graph illustrating the specific resistances ρ (μΩ·cm) of films of TaNₓ which are formed by using the respective apparatuses shown in FIGS. 1, 2 and 4.

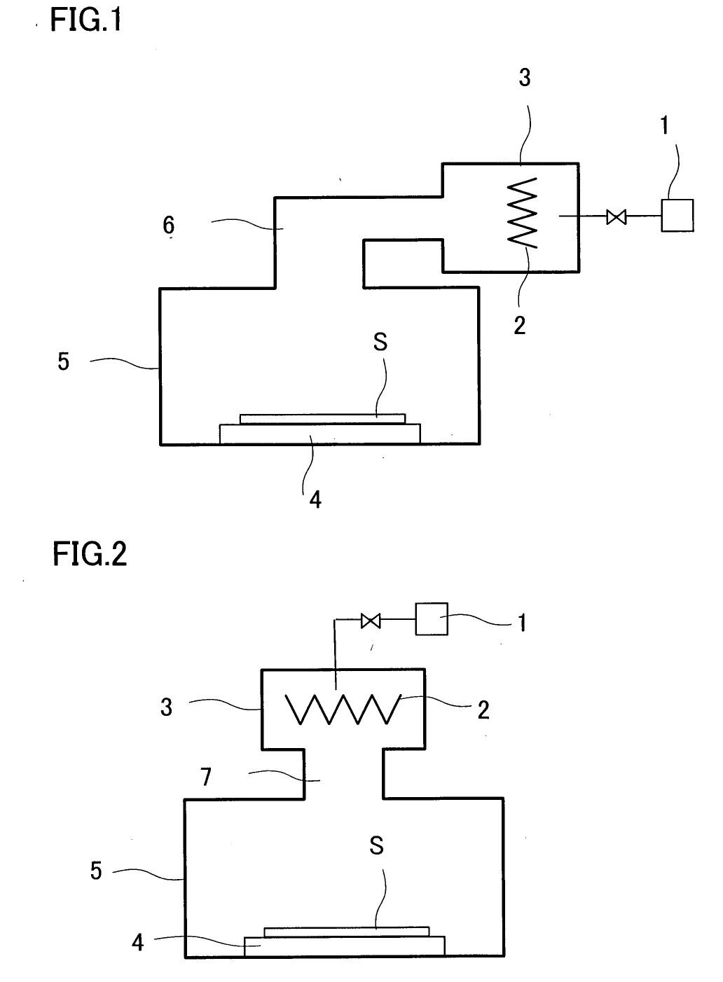

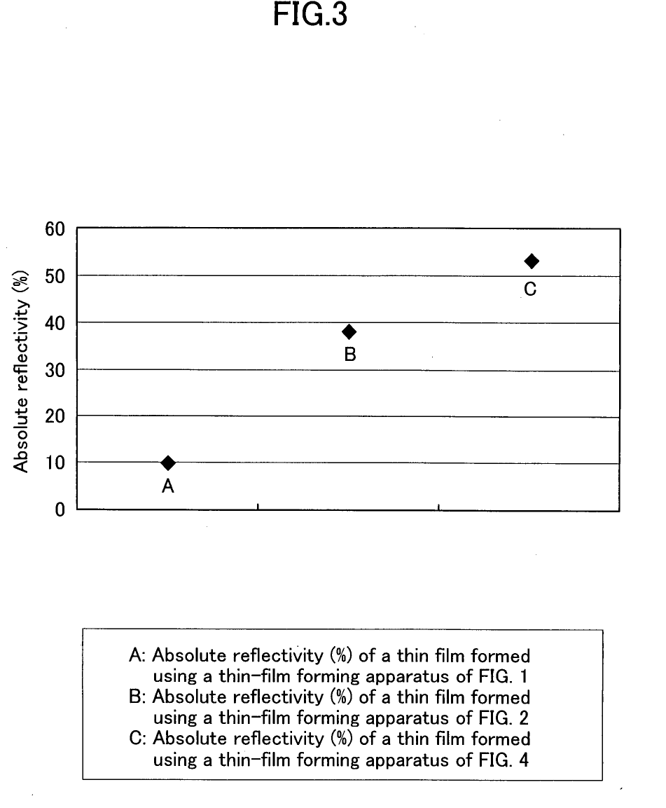

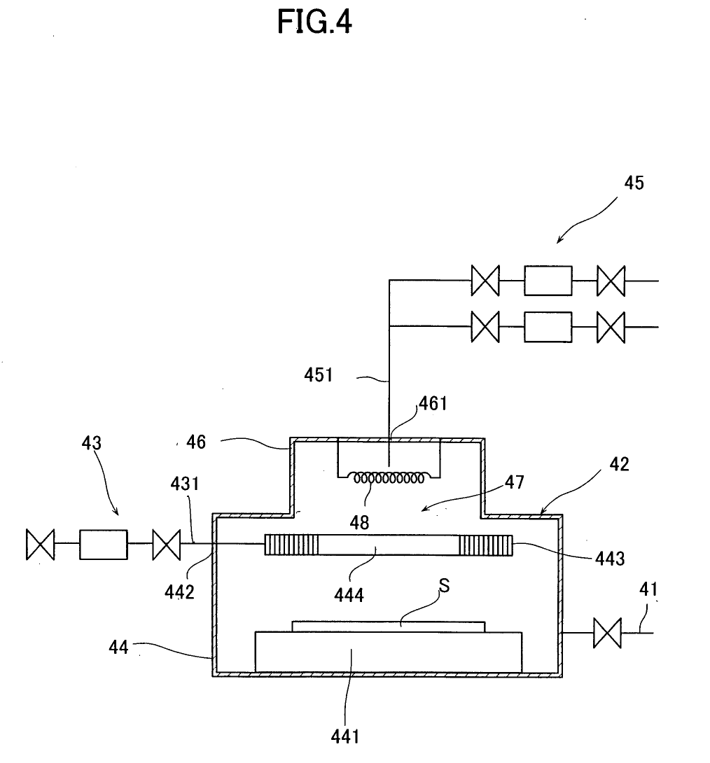

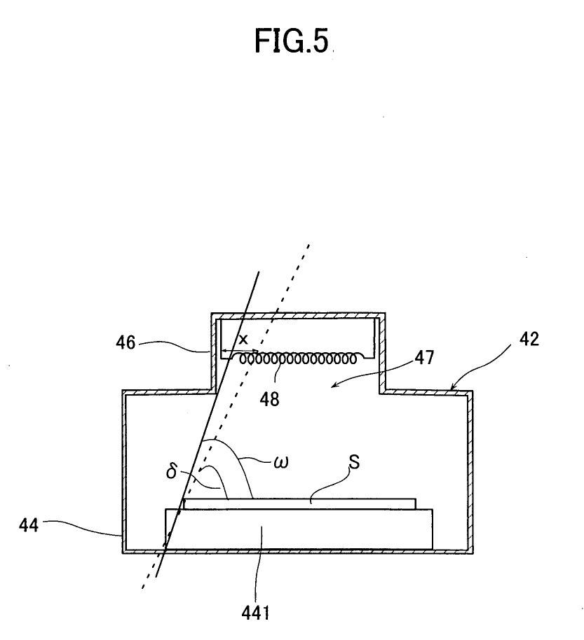

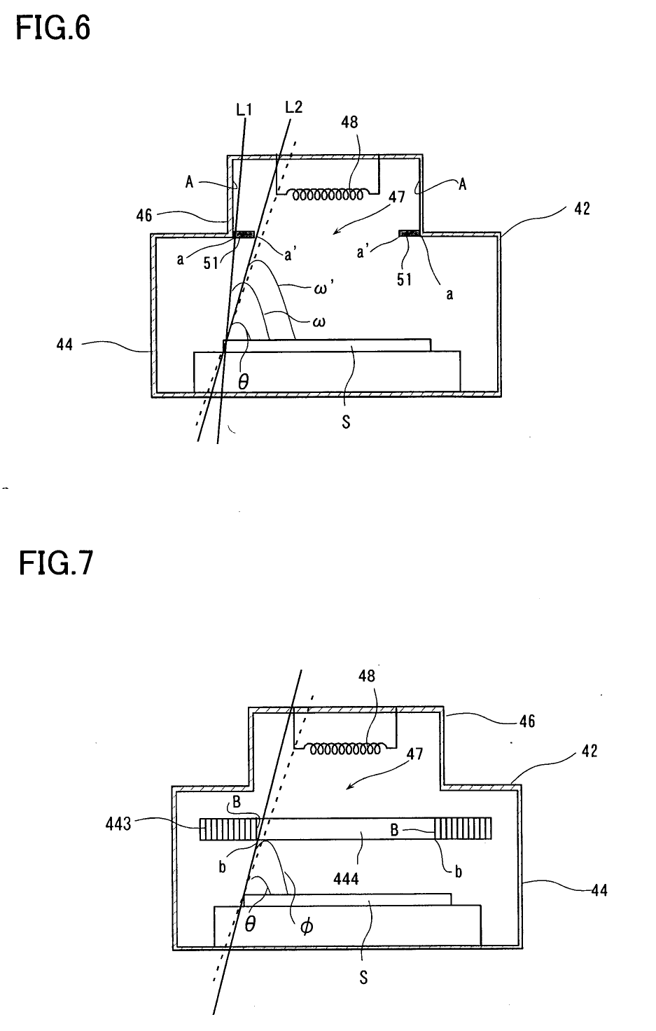

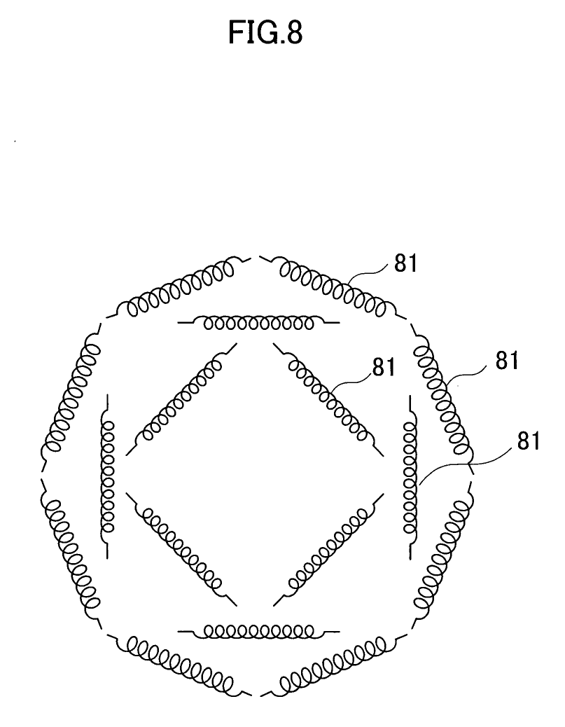

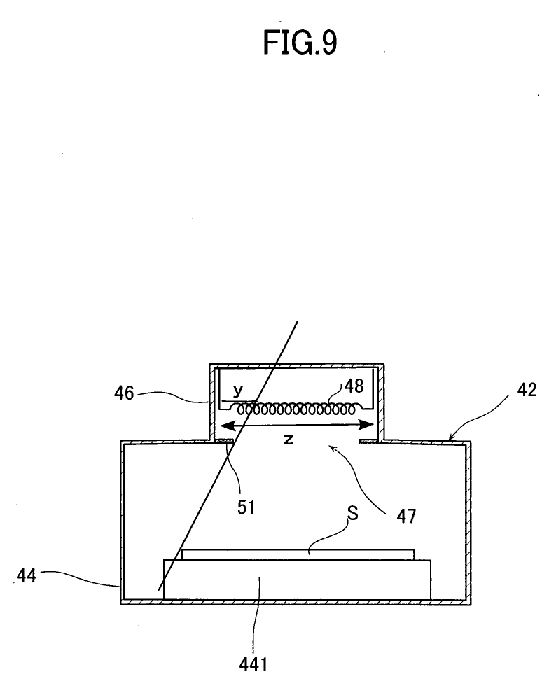

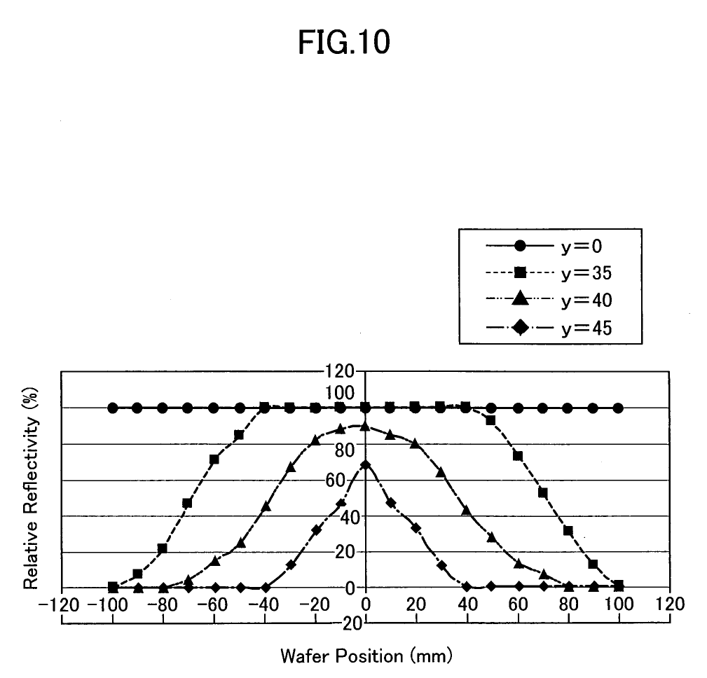

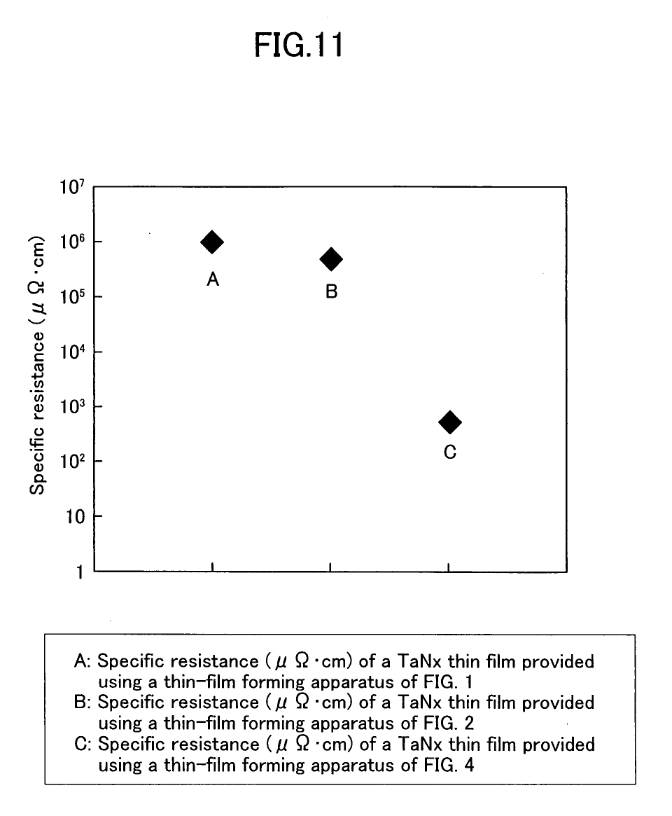

### EXPLANATION OF REFERENCE NUMERALS

41 Evacuation Means;
42 Vacuum Chamber;
43 Source Gas Supply Means;
44 Film Forming Chamber;
45 Reactant Gas Supply Means;
46 Catalyst Chamber;
47 Opening;
48 Catalyst source; and
S Substrate

1. A film forming apparatus comprising vacuum chamber including a film forming chamber provided with a source gas supply means and a substrate supporting stage and a catalyst chamber including a reactant gas supply means and a catalyst source located opposed to the substrate, the film forming chamber being connected to the catalyst chamber through an opening, said apparatus being characterized by that the catalyst source is disposed at a position satisfying ω≧δ, where ω is an angle included between the shortest linear line connecting the periphery of a substrate on the substrate supporting stage with the periphery of the opening and the substrate and where δ is an angle included between the shortest linear line connecting the periphery of the substrate with a point spaced apart from the periphery of the catalyst source toward the center thereof by a predetermined distance and the substrate.

2. The film forming apparatus as claimed in claim 1, characterized by that the predetermined distance is 0-35% of the length of the catalyst source.

3. A film forming apparatus comprising a vacuum chamber including a film forming chamber provided with a source gas supply means and a substrate supporting stage, and a catalyst chamber including a reactant gas supply means and a catalyst source located opposed to the substrate, the film forming chamber being connected to the catalyst chamber through an opening, said apparatus being characterized by that the catalyst source is disposed at a position satisfying ω≧θ, where ω is an angle included between the shortest linear line connecting the periphery of a substrate on the substrate supporting stage with the periphery of the opening and the substrate and where θ is an angle included between the shortest linear line connecting the periphery of the substrate with the edge of the catalyst source and the substrate.

4. The film forming apparatus as claimed in claim 1, characterized by that said distance between the catalyst source and the substrate is 0.5-1.5 times larger than the diameter of the substrate.

5. The film forming apparatus as claimed in claim 1, characterized by that said catalyst source is formed of at least one spiral high-melting-point metal wire.

6. The film forming apparatus as claimed in claim 5, characterized by that said high-melting-point metal wire is so located that it will not be bent by heat.

7. The film forming apparatus as claimed in claim 1, characterized by that a perforated partition is located within said opening.

8. The film forming apparatus as claimed claim 7, characterized by that the total area of perforation in said partition is 50% or more of the surface area of the partition.

9. The film forming apparatus as claimed in claim 1, characterized by that it further comprises a shower nozzle for supplying the source gas and including a central opening formed therethrough, said shower nozzle being located within said film forming chamber and that the shower nozzle is disposed at a position satisfying φ≧θ where φ is an angle included between the shortest linear line connecting the periphery of the substrate with the edge of the opening of the shower nozzle and the substrate and where θ is an angle included between the shortest linear line connecting the periphery of the substrate with the edge of the catalyst source and the substrate.

10. The film forming apparatus as claimed in claim 1, characterized by that it further comprises an evacuation means located on the bottom of said film forming chamber.

11. The film forming apparatus as claimed in claim 1, characterized by that it further comprises a cooling means located inside or outside of said catalyst chamber.

12. The film forming apparatus as claimed in claim 1, characterized by that it further comprises an isolation valve located in said opening.

13. The film forming apparatus as claimed in claim 12, characterized by that said isolation valve is a gate valve.

14. The film forming apparatus as claimed in claim 1, characterized by that it further comprises a shutter located in said opening.

15. A method of forming a film by using the film forming apparatus as claimed in claim 1.

16. The film forming apparatus as claimed in claim 3, characterized by that said distance between the catalyst source and the substrate is 0.5-1.5 times larger than the diameter of the substrate.

17. The film forming apparatus as claimed in claim 3, characterized by that said catalyst source is formed of at least one spiral high-melting-point metal wire.

18. The film forming apparatus as claimed in claim 3, characterized by that a perforated partition is located within said opening.

19. The film forming apparatus as claimed in claim 3, characterized by that it further comprises a shower nozzle for supplying the source gas and including a central opening formed therethrough, said shower nozzle being located within said film forming chamber and that the shower nozzle is disposed at a position satisfying φ≧θ where φ is an angle included between the shortest linear line connecting the periphery of the substrate with the edge of the opening of the shower nozzle and the substrate and where θ is an angle included between the shortest linear line connecting the periphery of the substrate with the edge of the catalyst source and the substrate.

20. A method of forming a film by using the film forming apparatus as claimed in claim 3.
